(19) United States
(12) Patent Application Publication
(10) Pub. No.: US 2009/0169826 A1
(43) Pub. Date: Jul. 2, 2009

(54) METHOD FOR PRODUCING A HEATABLE MOLDED BODY, IN PARTICULAR FOR EXTERIOR REARVIEW MIRRORS, WITH A HEATING ELEMENT

(75) Inventor: Norbert Kuerschner, Wedemark (DE)

Correspondence Address: REISING, ETHINGTON, BARNES, KISSELLE, P.C., P O BOX 4390, TROY, MI, 48099-4390, US

(73) Assignee: SCHEFENACKER-ENGELMANN SPIEGEL GMBH, Schwaikheim (DE)

(21) Appl. No.: 11/916,154

(22) PCT Filed: Jun. 9, 2006
(86) PCT No.: PCT/DE2006/000998

§ 371 Date: Aug. 12, 2008

(30) Foreign Application Priority Data
Oct. 6, 2005 (DE) 10 2005 026 766.1

(51) Int. Cl. B32B 27/12; B29C 45/14; C23C 14/34; B05D 3/12; B05D 1/36; B32B 3/00

(52) U.S. Cl. 428/172; 264/257; 204/192.1; 427/355; 427/402; 427/346; 442/394

(57) ABSTRACT

The invention relates to a method for producing a heatable moulded body, in particular for exterior rearview mirrors, with a heating element which is formed as an electrically contactable nonwoven fabric. The object of the invention is to provide an improved method for producing a moulded body of the generic type and an improved moulded body. This object is achieved by creating or placing a first layer of plastic in a mould, placing the nonwoven fabric on this first layer of plastic and subsequently applying a second layer of plastic to the first layer of plastic and the nonwoven fabric, the first and second layers of plastic electrically insulating the nonwoven fabric completely apart from the electrical terminals.

### BACKGROUND OF THE INVENTION

The invention is based on a priority patent application DE 10 2005 026 766.1 which is hereby incorporated by reference.

The invention relates to a method for producing a heatable molded body, in particular for exterior rearview mirrors, comprising a heating element, which is formed as an electrically contactable nonwoven fabric and a heatable molded body as such.

From DE 195 09 153 A1, a molded body with a heating device is known, in particular for exterior rearview mirrors of a motor vehicle, having a heating layer, comprising electrically connected carbon fibers, which are stiffened with a binder material and reinforced with plastic in a press process, wherein said plastic penetrates into the open spaces between the carbon fibers. After stiffening the carbons fiber by means of the binder material, the open spaces are open or only partially closed, so that the plastic material, permeating through the open spaces in an injection molding process, injects behind the carbon fibers. A mirror glass is glued onto the surface of the molded body, close to the carbon fibers, which is then inserted into an exterior rearview mirror together with the heatable molded body.

The disadvantage of the known state of the art is the fact, that the carbon fibers are not completely embedded into the plastic material, so that the carbon fibers protrude from the surface. As a consequence, an electrical contact is established with the mirrored backside of the glued on glass, which leads to an increased corrosion. The mirror glass loses its reflection capability and has to be replaced, which is complex.

### SUMMARY OF THE INVENTION

Thus, it is the object of the invention to provide a better method for producing a molded body of this type, and an improved molded body. This object is accomplished according to the invention by creating or placing a first layer of plastic in a mold, in particular an injection molding or injection embossing tool, wherein said layer is impermeable for electrically conductive fibers, e.g. carbon fibers of a carbon fiber- or carbon fiber/glass fiber mixed nonwoven fabric, which is placed onto the first plastic layer. The first plastic layer is either prefabricated and inserted into the molding tool, or generated in a first step, e.g. injection molding step, or injection molding embossing step, e.g. in a rotating plate mold, in the injection molding tool. Then, the carbon fiber nonwoven fabric, or mixed nonwoven fabric is inserted into the mold.

Subsequently, a second plastic layer is applied onto the first plastic layer and the nonwoven fabric by injecting or inserting plastic material into the mold. Thus, the nonwoven fabric is enclosed between the two plastic layers, so that the nonwoven fabric is electrically insulated, besides the necessary electric connections, which are necessary for providing the electric energy for creating the heating effect. In particular, an electrical insulation in the direction towards the side of the first plastic layer occurs, which faces away from the nonwoven fabric, so that when applying a mirror material, either a prefabricated mirror glass or a reflecting coating, no impairment occurs through increased corrosion.

A refinement of the invention provides that the two plastic layers are bonded together, in particular that the first and the second plastic layer melt together, so that the nonwoven fabric is at least completely enclosed at the rims. By means of this bonded connection, created by heat and pressure, the carbon fiber woven fabric can be embedded into the plastic layers, which creates an improved thermal conduction, whereby a faster heating e.g. of the mirror surface occurs.

The first plastic layer can be generated through injection molding or injection embossing, wherein the injection molding tool or the injection embossing tool is a portion of the final mold for the molded body. After producing the first plastic layer, the mold is opened, the nonwoven fabric is inserted, and another opposite mold piece is associated with the first plastic layer, so that through another injection molding or injection embossing process, the final molded body can be created. The molding tool is thus preferably provided as rotating disk mold, so that at least one molded piece can be generated in each process step, by alternatively associating the respective opposite portions with the first molded part.

As an alternative to generating the first plastic layer in the molding tool, it is possible to apply the second plastic layer through the so-called in-mold-method, thus, so that initially a complete foil with nonwoven fabric is inserted, and this combination is then injected with material from behind.

In order to reach a heat conduction effect, which is as good as possible, it is provided that the first plastic layer is formed relatively thin, e.g. as thick as the nonwoven fiber layer. The necessary stiffness is assured through depositing the second plastic layer, which is thus provided e.g. with reinforcement bridges. Alternatively, it is possible that the first plastic layer is provided stiff, and only the second plastic layer forms a smooth outer surface.

It is provided in another process step that the side of the first plastic layer, facing away from the nonwoven fabric, possibly the far side of the second plastic layer is mirrored, in particular sputtered, or chromed, or otherwise coated in a reflecting manner, so that a complete assembly comprised of heatable molded body and mirror, can be produced. Instead of a coating, also a thin walled mirror glass can be glued on.

In order to achieve an appealing optical quality, the respective side of the plastic layer, which is to be coated, is reworked, preferably polished, in order to achieve a surface roughness, which corresponds to the one of glass. When a respective mold quality is provided, it may not be necessary for a surface post treatment to be performed after the molding process.

In order to obtain a usable and durable exterior mirror, in a refinement of the invention, a scratch resistant coating is applied after the mirroring, e.g. provided as a thin glass layer. Thin glass has the advantage of low weight, good optical properties and a very good mechanical stability.

A surprisingly good method for mounting a thin glass layer on a molded body provides, that between the mirrored layer and the thin glass layer a glue layer, in particular a silicone gel layer, an EP-glue layer, or a PUR-glue layer is disposed, which also compensates for an unevenness in the mirrored layer, or on the molded body, besides mounting the thin glass layer.

In order to be able to mount the thin glass on the molded body in an even manner, the molded body is subjected to vibrations after depositing the glue, e.g. the silicone gel, so that an even distribution of the glue is accomplished under the thin glass.

The heatable molded body provides a first plastic layer, a nonwoven fabric with electrical contacts, and a second plastic layer, wherein the second plastic layer is molded or embossed onto the nonwoven fabric and the first plastic layer. The nonwoven fabric is thus completely insulated besides the electrical contacts and it is thus substantially enclosed by the plastic layers. Thereby, it is possible, that a substantially corrosion protected surface is provided on the side of the plastic layers, facing away from the nonwoven fabric, so that the deposited mirror layers are not impaired optically.

The plastic layers are thus bonded together in a useful manner, so that the nonwoven fabric is encapsulated, possibly the nonwoven carbon fiber fabric protrudes on the narrow sides. Depending on the application, the plastic layers can be comprised of different materials. While e.g. the first plastic layer has to be as smooth as possible on the side facing away from the nonwoven fabric, in order for a direct coating with a reflecting material to be possible, a high mechanical strength can be required for the second plastic layer, in order to assure sufficient form stability. Furthermore, it is essential that no fibers of the nonwoven fabric penetrate through the plastic layers to the surface, which is provided with a reflecting medium. The reflective coating can be performed in particular through sputtering, chroming, or metal vapor deposition.

In an advantageous manner, the reflective coating is provided with a scratch resistant coating, in order to protect it from environmental influences. Thus, thin glass, which is disposed above the reflective coating of the molded body, is optically or mechanically advantageous. The thin glass layer in one variant is connected to the reflective layer by means of glue, e.g. silicone gel, EP-glue, or PUR-glue, in order to achieve a safe assembly and good optical quality.

An alternative provides that the reflecting coating itself is coated with zinc doted indium oxide, which, on the hand, is transparent, and on the other hand, conductive. Thus, it is possible to provide another heat source besides the nonwoven heating fabric by means of the layer of zinc doted indium oxide, by means of which a frosting of the mirror can be quickly removed.

Additionally or as a supplement, it is provided that a liquid crystal layer is disposed over the reflective layer, which is covered by a scratch resistant coating, in particular thin glass. By means of this liquid crystal layer, the mirror can be darkened through applying a voltage, whereby the risk of blinding is reduced for the driver. For automatic dimming of the exterior mirror, the liquid crystal layer is provided with electrical contacts, which are connected to a voltage source and a brightness sensor, which darkens the mirror when a predetermined maximum value is passed.

### BRIEF DESCRIPTION OF THE DRAWINGS

Subsequently, the invention is described in more detail with reference to the figures. It is shown in:

FIG. 1 a molded body in a sectional view;

FIG. 2 a molded body according to FIG. 1 with reflective and thin glass coating;

FIG. 3 a molded body according to FIG. 1 with reflective and scratch resistant coating;

FIG. 4 a molded body according to FIG. 2 with a liquid crystal layer; and

FIG. 5 a molded body according to FIG. 2 with a glue layer.

### DETAILED DESCRIPTION OF THE DRAWINGS

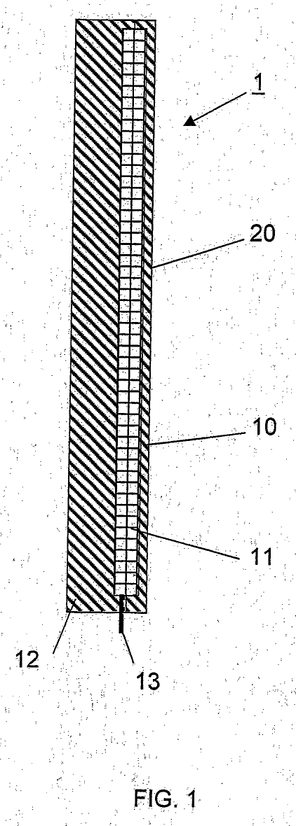

FIG. 1 shows a molded body 1 in a sectional view. The molded body 1 is comprised of a first plastic layer 10 and a second plastic layer 12, bonded therewith, wherein between the first plastic layer 10 and the second plastic layer 12 a nonwoven fabric 11 is inserted and enclosed. Only electrical contacts 13, which are connected with the electrically conducting nonwoven fabric, presently a nonwoven carbon fiber fabric 11, protrude for the purpose of an electrical contacting from the molded body 1. It can be derived from the figure that the nonwoven carbon fiber fabric 11 is completely enclosed by the plastic layers 10, 12, which are bonded to each other. This way, it is assured that a complete electrical insulation of the nonwoven carbon fiber fabric 11 besides the electrical contacts 13 is provided. Instead of a pure carbon fiber fabric, also a mixed fabric from carbon fibers and glass fibers can be provided, or an alternative nonwoven fabric, whose fibers are at least partially electrically conductive.

When a mirror glass is to be deposited on the side 20 of the first plastic layer 10, facing away from the nonwoven carbon fiber fabric, there is no risk that an increased corrosion of the chromed silver plated, or otherwise reflecting glass layer is performed through an electrical contact.

Through avoiding a pass-through of the fibers of the carbon fiber fabric 11, it is possible that at least one exterior side of the molded body 1 can be coated directly reflective, e.g. sputtered, chromed, or metal vapor deposited. This way, molded bodies 1 can be established in few process steps with a low materials consumption, wherein said molded bodies can be installed into heatable mirrors in rearview mirrors, in particular exterior rearview mirrors.

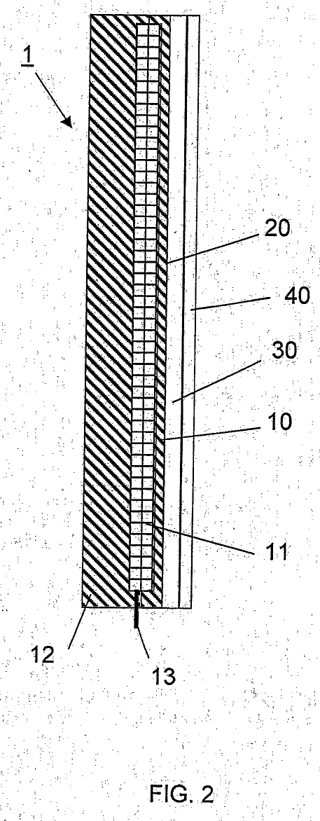

In FIG. 2, the molded body 1 according to FIG. 1 is illustrated, wherein a reflecting layer 30 is deposited on one side, e.g. a chromium layer. Also other reflective layers 30 can be deposited on the outside of the molded body 1, so that the molded body 1 acts as a carrier plate for a mirror, in particular for an exterior mirror. The nonwoven heating layer 11 is thus disposed relatively close to the surface of the molded body 1, on which the reflective layer 30 is deposited, in order to be able to effectuate a defrosting of the exterior rearview mirror as quickly as possible. In order to protect the reflective coating 30 from environmental impacts, a scratch resistant coating 40 is applied thereon, which is comprised e.g. from thin glass.

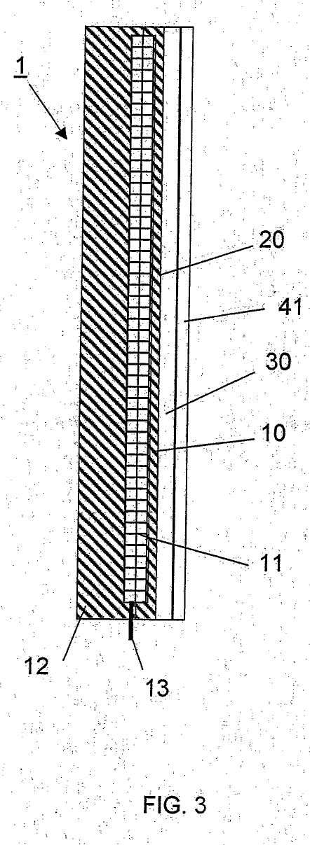

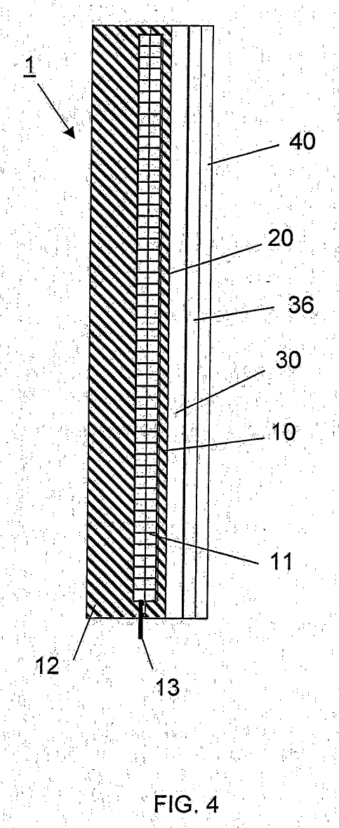

In FIG. 3, a coated molded body 1 according to FIG. 2 is illustrated. Instead of a thin glass layer 40, zinc doted indium oxide 41 is deposited on the reflective layer 30, which is transparent as well as electrically conductive. By means of contacts, which are not shown, power can be conducted through the scratch resistant coating 41, so that an additional heat source is provided in addition to the nonwoven heated fabric 11. In FIG. 4, a molded body 1, according to FIG. 2, is illustrated, in which between the reflective coating 30 and the scratch resistant coating 40, provided in this case as thin glass, a liquid crystal layer 36 is disposed, which is provided changeable in its brightness or light permeability by applying a voltage. Thereby, it is possible to manually or automatically vary the reflected light quantity, e.g. by measuring the light quantity impacting the reflective layer 30, e.g. by means of a brightness sensor, and by darkening the liquid crystal layer 36, when going over a predetermined value.

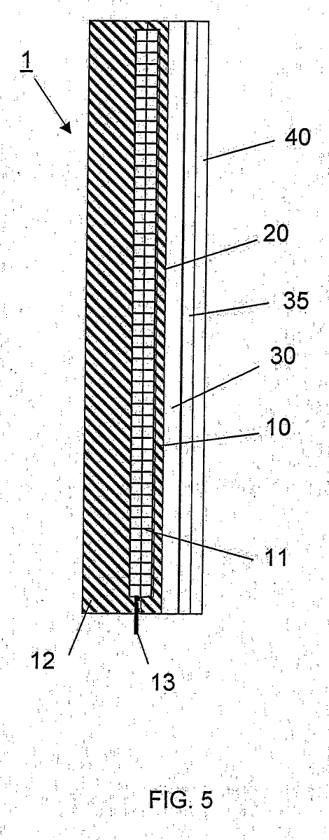

FIG. 5 shows a molded body 1 according to FIG. 2, in which the thin glass layer 40 is mounted to the reflecting layer 30, by means of a glue layer 35, e.g. silicone gel. An even distribution of the glue layer 35, in particular in case of spherically curved surfaces, is advantageously performed by exposing the molded body 1 to vibrations, after depositing the glue, so that an even distribution of the glue 35 between the reflective coating 30 and the scratch resistant coating 40 is performed.

What is claimed is:

1. A method for producing a heatable molded body, in particular for exterior rearview mirrors, comprising a heating element, which is configured as an electrically contactable non-woven carbon fabric, wherein in a molding tool, a first plastic layer (10) is created or inserted, and the non-woven fabric (11) is placed onto said first plastic layer (10), and subsequently, a second plastic layer (12) is placed onto the first plastic layer (10) and the non-woven fabric (11), wherein the first and the second plastic layer (10, 12) electrically insulate the non-woven fabric (11) completely, besides the electrical connections (13).

2. A method according to claim 1, wherein the plastic layers (10, 12) are bonded to one another, in particular melted together.

3. A method according to claim 1 or 2, wherein the non-woven fabric (11) is configured as a non-woven carbon fiber fabric or is a mixed non-woven fabric made of carbon- and glass fiber.

4. A method according to one of the preceding claims, wherein the first plastic layer (10) is produced by injection molding or injection embossing in the molding tool, wherein the molding tool is a component of the molding tool for the molded body (1).

5. A method according to one of the preceding claims, wherein the molding tool is configured as an injection molding tool or as an injection embossing tool.

6. A method according to one of the preceding claims, wherein the molding tool is configured as a rotating plate.

7. A method according to one of the claims 1 through 15, wherein the second plastic layer is deposited in an in-mold process.

8. A method according to one of the preceding claims, wherein the first plastic layer (10) is produced in a thickness which corresponds to the thickness of the non-woven carbon fiber fabric (11).

9. A method according to one of the preceding claims, wherein the side (20) of the first plastic layer (10), facing away from the non-woven fabric (11) is mirrored, in particular sputtered or chromed.

10. A method according to claim 9, wherein the side (20) to be mirrored to be mirrored of the first plastic layer (10) is polished after the molding process and before coating.

11. A method according to claim 9 or 10, wherein a scratch free coating (40, 41) is deposited after mirroring.

12. A method according to one of the claims 7 through 11, wherein a thin glass (40) is deposited after mirroring.

13. A method according to claim 12, wherein between the mirrored layer (30) and the thin glass layer (40), a glue layer, in particular a silicon gel layer (35), an EP-glue layer, or a PUR-glue layer is disposed.

14. A method according to claim 13, wherein after depositing the glue layer (35) the molded body (1) is exposed to vibrations.

15. A heatable molded body, in particular for exterior rearview mirrors, comprising a first plastic layer (10), a non-woven fabric (11) with electrical contacts (13), and a second plastic layer (12), which is injected or embossed onto the non-woven fabric (11) and the first plastic layer (10), wherein the non-woven fabric (11) is completely insulated electrically besides the electrical contacts (13).

16. A molded body according to claim 15, wherein the plastic layers (10, 12) are bonded together.

17. A molded body according to claim 15 or 16, wherein the plastic layers (10, 12) are comprised of different layers.

18. A molded body according to one of the claims 15 through 17, wherein the outer layer (20) of the first plastic layer (10) is coated, so it becomes reflective, in particular sputtered, chromed or deposited with metal vapor.

19. A molded body according to claim 18, wherein the reflective coating (30) is provided with a scratch resistant coating (40, 41).

20. A molded body according to claim 18 or 19, wherein a thin glass layer (40) is disposed on top of the reflective coating (30).

21. A molded body according to claim 20, wherein the thin glass layer (40) is connected to the reflective layer (30) through a glue layer (35), in particular a silicon gel, an EP-glue or a PUR-glue.

22. A molded body according to claim 18 or 19, wherein the reflective coating (30) is coated with tin doted indium oxide (41).

23. A molded body according to one of the claims 18 through 21, wherein a liquid crystal layer (36) is disposed on top of the reflective coating (30), wherein said liquid crystal layer is covered by a scratch resistant coating (40, 41), in particular thin glass (40).

24. A molded body according to claim 23, wherein the liquid crystal layer (36) is provided with electrical contacts, which are connected to a voltage source and to a brightness sensor, which darkens the liquid crystal layer (36), when a predetermined maximum value is exceeded.

25. A molded body according to one of the claims 15 through 24, wherein the non-woven fabric (11) is configured as a non-woven carbon fiber fabric or as mixed non-woven fabric made of carbon fiber or glass fiber.
